(19) United States
(12) Patent Application Publication
(10) Pub. No.: US 2026/0316115 A1
(43) Pub. Date: Oct. 15, 2026

(54) ULTRASONIC ACOUSTIC PRESSURE CONTROL APPARATUS AND CONTROL METHOD THEREOF

(71) Applicants: Hyundai Motor Company, Seoul (KR); Kia Corporation, Seoul (KR); INHA UNIVERSITY RESEARCH AND BUSINESS FOUNDATION, Incheon (KR)

(72) Inventors: Dong Gu KIM, Hwaseong-si (KR); Deok Woo Yun, Hwaseong-si (KR); Gwan Sik Kim, Hwaseong-si (KR); Seok Min Lee, Hwaseong-si (KR); Kyong Hwa Song, Hwaseong-si (KR); Jang Hyeon Lee, Hwaseong-si (KR); Howuk Kim, Incheon (KR)

(73) Assignees: Hyundai Motor Company, Seoul (KR); Kia Corporation, Seoul (KR); INHA UNIVERSITY RESEARCH AND BUSINESS FOUNDATION, Incheon (KR)

(21) Appl. No.: 19/413,935

(22) Filed: Dec. 9, 2025

(30) Foreign Application Priority Data
Apr. 14, 2025 (KR) 10-2025-0048240

(51) Int. Cl. B06B 1/02; B60Q 9/00; G06F 3/01; H03H 9/46

(52) U.S. Cl. CPC B06B 1/0207; B60Q 9/00; G06F 3/016; G06F 3/017; H03H 9/46

(57) ABSTRACT

In an ultrasonic acoustic pressure control apparatus and a control method thereof, an ultrasonic acoustic pressure control technology may adjust a tactile resolution more precisely and suppress unnecessary tactile feedback occurring due to a grating lobe and a side lobe.

### CROSS-REFERENCE TO RELATED APPLICATIONS

The present application claims priority to Korean Patent Application No. 10-2025-0048240, filed on Apr. 14, 2025, the entire contents of which is incorporated herein for all purposes by this reference.

### FIELD OF THE PRESENT DISCLOSURE

The present disclosure herein relates to an ultrasonic acoustic pressure control apparatus and a control method thereof.

### BACKGROUND

As a non-contact interface technology is developed in recent years, an air tactile feedback technology using an ultrasonic wave has been actively researched.

A conventional tactile interface is realized based on a physical button, a touch screen, or a wearable haptic device. This method, however, has a limitation of requiring a direct contact to a body of a user.

Thus, a technology of adjusting acoustic pressure in the air by use of an ultrasonic wave and providing tactile feedback at a specific point has been developed. The ultrasonic-based tactile feedback technology operates based on a principle of amplifying an acoustic pressure at a specific point by use of an array of ultrasonic transducers and allowing a user to feel a tactile sensation. The present technology may be applied to various fields such as interfaces used in vehicles, virtual reality (VR) and augmented reality (AR) environments, medical simulations, and games.

However, since a tactile resolution is fixed by a constant frequency and a size of an ultrasonic transducer in the conventional ultrasonic array-based tactile feedback technology, a limitation may occur so that tactile feedback is difficult to be finely adjusted in a specific region, and as a grating lobe and a side lobe occur, a user may feel a tactile sensation at an unintended position or a tactile effect is distorted.

To solve the above-described limitations, an ultrasonic acoustic pressure control apparatus capable of adjusting the tactile resolution and controlling the grating lobe and the side lobe and a control method thereof are required.

### BRIEF SUMMARY

According to various aspects of the present disclosure, the present disclosure provides an ultrasonic acoustic pressure control apparatus configured for variably adjusting a tactile resolution and suppressing unnecessary tactile feedback caused by a grating lobe and a side lobe and a control method thereof.

Technical objects to be solved by the present disclosure are not limited to the aforementioned technical objects and unmentioned technical objects will be clearly understood by those skilled in the art to which the present disclosure belongs.

According to various aspects of the present disclosure, the present disclosure provides an ultrasonic acoustic pressure control apparatus including an ultrasonic transducer array including a plurality of ultrasonic transducers, an ultrasonic control circuit including a processor and controlling the ultrasonic transducer array, and a user input interface operatively connected to the ultrasonic control circuit, detecting a position and a gesture of a hand of a user, and providing detected information related to the position and the gesture of the hand of the user, to the ultrasonic control circuit, wherein the ultrasonic control circuit divides a control window set based on the position of the hand into a target region and a suppression region and controls the ultrasonic transducer array so that a difference in acoustic pressure between the target region and the suppression region is adjusted to be greater than or equal to a preset threshold value.

According to various aspects of the present disclosure, the ultrasonic control circuit may be further configured to control the ultrasonic transducer array by performing a phase control or an amplitude control for pressure waves generated from the plurality of ultrasonic transducers.

According to various aspects of the present disclosure, the ultrasonic control circuit may be further configured to control the ultrasonic transducer array to generate a first acoustic pressure in the target region by aligning phases of the pressure waves and increasing amplitudes of the pressure waves in the target region, and control the ultrasonic transducer array to generate a second acoustic pressure in the suppression region by dispersing the phases of the pressure waves and reducing the amplitudes of the pressure waves in the suppression region, wherein a difference between the first acoustic pressure and the second acoustic pressure is greater than or equal to a preset threshold value.

According to various aspects of the present disclosure, the ultrasonic control circuit may be further configured to reduce a grating lobe and a side lobe in the suppression region.

According to various aspects of the present disclosure, the ultrasonic control circuit may be further configured to apply an acoustic filtering for the difference in the acoustic pressure between the target region and the suppression region

According to various aspects of the present disclosure, the ultrasonic control circuit may be further configured to generate, based on a first acoustic pressure transfer function (RB) for the target region and a second acoustic pressure transfer function (RD) for the suppression region, a third acoustic pressure transfer function (RB-αRD), and use an eigenvector corresponding to a largest eigenvalue of the third acoustic pressure transfer function, wherein a denotes a weight function that adjusts the difference in the acoustic pressure between the target region and the suppression region

According to various aspects of the present disclosure, the ultrasonic control circuit be further configured to adjust a size of the control window to adjust a tactile resolution.

According to various aspects of the present disclosure, a method for controlling an ultrasonic acoustic pressure control apparatus includes generating ultrasonic waves by use of an ultrasonic transducer array including a plurality of ultrasonic transducers, detecting a position and a gesture of a hand of a user to provide detected information to an ultrasonic control circuit, dividing a control window set based on the position of the hand into a target region and a suppression region, and controlling the ultrasonic transducer array so that a difference in acoustic pressure between the target region and the suppression region is greater than or equal to a set threshold value.

According to various aspects of the present disclosure, the generating of the ultrasonic waves may include controlling the ultrasonic transducer array by performing a phase control or an amplitude control for pressure waves generated from the plurality of ultrasonic transducers.

According to various aspects of the present disclosure, the controlling of the ultrasonic transducer array may include controlling the ultrasonic transducer array to generate a first acoustic pressure in the target region by aligning phases of the pressure waves and increasing amplitudes of the pressure waves in the target region, and controlling the ultrasonic transducer array to generate a second acoustic pressure in the suppression region by dispersing the phases of the pressure waves and reducing the amplitudes of the pressure waves, wherein a difference between the first acoustic pressure and the second acoustic pressure is greater than or equal to a preset threshold value.

According to various aspects of the present disclosure, the controlling of the ultrasonic transducer array to generate a second acoustic pressure in the suppression region may include reducing a grating lobe and a side lobe in the suppression region.

According to various aspects of the present disclosure, the controlling of the ultrasonic transducer array may include applying an acoustic filtering for the difference in the acoustic pressure between the target region and the suppression region.

According to various aspects of the present disclosure, the applying of the acoustic filtering may include generating, based on a first acoustic pressure transfer function (RB) for the target region and a second acoustic pressure transfer function (RD) for the suppression region, a third acoustic pressure transfer function (RB-αRD), and using an eigenvector corresponding to a largest eigenvalue of the third acoustic pressure transfer function, wherein a denotes a weight function that adjusts the difference in the acoustic pressure between the target region and the suppression region

According to various aspects of the present disclosure, the method may further include adjusting a tactile resolution by adjusting a size of the control window and a size of a focal point.

Also, according to an exemplary embodiment of the present disclosure, there is disposed a vehicle including an ultrasonic acoustic pressure control apparatus described above.

### BRIEF DESCRIPTION OF THE DRAWINGS

FIG. 1 is a block diagram illustrating an ultrasonic acoustic pressure control apparatus according to an exemplary embodiment of the present disclosure.

FIG. 2A and FIG. 2B are illustrations for comparing an ultrasonic acoustic pressure control method according to an exemplary embodiment of the present disclosure with that of a related art.

FIG. 3A and FIG. 3B are illustrations for comparing an amplitude variation of each transducer when acoustic filtering is applied to the ultrasonic acoustic pressure control method according to an exemplary embodiment of the present disclosure with that of the related art.

FIG. 4A and FIG. 4B are illustrations for visually illustrating comparison of an improvement effect of a tactile resolution achieved by the ultrasonic acoustic pressure control method according to an exemplary embodiment of the present disclosure with that achieved by the related art.

FIG. 5A and FIG. 5B are illustrations for visually comparing of an effect of acoustic filtering achieved by the ultrasonic acoustic pressure control method according to an exemplary embodiment of the present disclosure with that achieved by the related art.

FIG. 6 is a flowchart illustrating a process of generating an acoustic filter value in the ultrasonic acoustic pressure control method according to an exemplary embodiment of the present disclosure.

### DETAILED DESCRIPTION

Since the present disclosure may have diverse modified embodiments, exemplary embodiments are illustrated in the drawings and are described in the detailed description of the present disclosure. However, this does not limit the present disclosure within the specific embodiments and it should be understood that the present disclosure covers all the modifications, equivalents, and replacements within the idea and technical scope of the present disclosure.

In the present specification, the suffixes “module” and “unit” are used merely for nominal distinction between components and should not be interpreted as implying that the components are physically or chemically separated or that they can be separated.

It will be understood that although the terms of “first” and “second” are used herein to describe various elements, these elements should not be limited by these terms. These terms may be used solely to differentiate one component from another in name, and their sequential meanings are understood through the context of the description rather than by the names themselves.

The term “and/or” is used to include all possible combinations of the listed items. For example, “A and/or B” includes all three cases of “A”, “B”, and “A and B”.

It will also be understood that when an element is referred to as being “connected to” or “engaged with” another element, it can be directly connected to the other element, or intervening elements may also be present.

In the following description, the technical terms are used only for explaining a specific exemplary embodiment while not limiting the present disclosure. The terms of a singular form may include plural forms unless referred to the contrary. The meaning of ‘include’ or ‘comprise’ specifies a property, a region, a fixed number, a step, a process, an element and/or a component but does not exclude other properties, regions, fixed numbers, steps, processes, elements and/or components.

Unless terms used in an exemplary embodiment of the present disclosure are defined differently, the terms may be construed as meaning known to those skilled in the art. Terms such as terms that are generally used and have been in dictionaries should be construed as having meanings matched with contextual meanings in the art. In the present description, unless defined clearly, terms are not ideally, excessively construed as formal meanings.

Also, the terms unit, control unit, control device, or control circuit are widely used to name devices that control specific functions and do not refer to a generic functional unit. Also, the devices denoted by the names may include a communication device that communicates with another control circuit or sensor to control the corresponding function, a computer-readable recording medium that stores an operation system, a logic command, and input/output information, and at least one processor that performs determinations, decisions, and calculations required for function control.

On the other hand, the processor may include semiconductor integrated circuits and/or electronic elements that perform at least one or more of comparisons, determinations, calculations, and decisions to achieve programmed functions. For example, the processor may be a computer, a microprocessor, CPU, ASIC, an electronic circuitry (logic circuits), or a combination thereof.

The processor may be electrically connected to the memory, and the processor may be configured to retrieve data from the memory and record data therein. The memory and the processor may be integrated with each other or physically separated from each other.

Hereinafter, various exemplary embodiments of the present disclosure will be described with reference to the accompanying drawings.

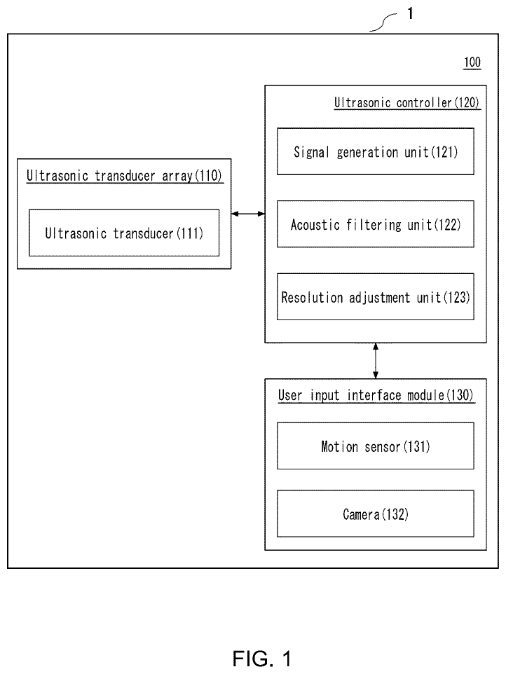

FIG. 1 is a block diagram illustrating a vehicle 1 including an ultrasonic acoustic pressure control apparatus 100 according to an exemplary embodiment of the present disclosure.

Referring to FIG. 1, an ultrasonic acoustic pressure control apparatus 100 according to an exemplary embodiment of the present disclosure may include an ultrasonic transducer array 110 and an ultrasonic control circuit 120.

The ultrasonic transducer array 110 includes a plurality of ultrasonic transducers 111 spaced a predetermined distance from each other and receives a control signal supplied from the ultrasonic control circuit 120 to emit an ultrasonic wave. The ultrasonic transducer array 110 may include a structure in which the plurality of ultrasonic transducers 111 are disposed in a matrix form, and each transducer 111 may be designed to individually adjust a phase and an amplitude of the corresponding pressure wave. According to an exemplary embodiment of the present disclosure, acoustic pressure may be concentrated at a focal point 160, at which a hand of a user is disposed, to provide tactile feedback by use of the ultrasonic transducer array 100.

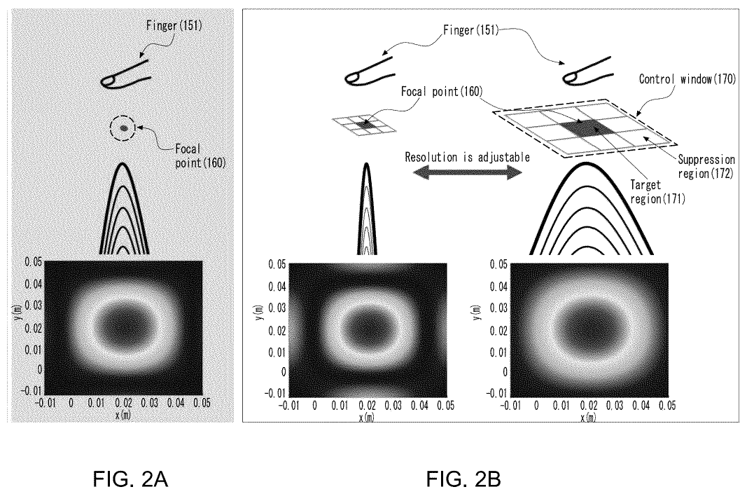

The conventional technology is required to increase the number of ultrasonic transducers 111 for improving a focal resolution, which may result in increased costs and system complexity. According to an exemplary embodiment of the present disclosure, however, a control method configured for improving the focal resolution without increasing the number of transducers 111 may be applied. This will be described later in detail with reference to FIG. 2.

The ultrasonic control circuit 120 is configured to control a phase and an amplitude of each of the plurality of transducers 111 of the ultrasonic transducer array 110, so that acoustic pressure is concentrated to the target focal point 160.

The ultrasonic control circuit 120 includes a signal generation unit 121, an acoustic filtering unit 122, and a resolution adjustment unit 123.

The signal generation unit 121 may perform a function of generating an electrical signal to be supplied to each of the ultrasonic transducers 111, set a frequency and an amplitude of an ultrasonic wave, and adjust the signal based on the target focal point 160.

The acoustic filtering unit 122 may set a control window 170 that divides the ultrasonic transducer array 110 into a target region 171 and a suppression region 172 and apply an acoustic filtering method for adjusting an acoustic pressure difference between the target region 171 and the suppression region 172. An acoustic pressure transfer function may be configured to increase the acoustic pressure in the target region 171 and minimize the acoustic pressure in the suppression region 172, and an optimized acoustic filtering value may be determined by use of an eigenvector corresponding to a largest eigenvalue of the acoustic pressure transfer function. The determined acoustic filtering value may be used to determine phase and amplitude values for each transducer 111, which maximize an energy difference between the target region 171 and the suppression region 172. This may allow a grating lobe and a side lobe occurring in the suppression region 172 to be effectively removed and tactile feedback occurring in the target region 170 to be more clearly maintained.

The resolution adjustment unit 123 may adjust a size of the control window 170 to change a size of the target region 171. When a user requires fine tactile feedback, the control window 170 may be contracted to concentrate acoustic pressure to a smaller region. On the other hand, when wider tactile feedback is required, the control window 170 may be expanded to increase a size of the focal point 160.

The resolution adjustment unit 123 may be designed to adjust the resolution in real-time based on a position of a hand of the user and an operation environment.

The user input interface module 130 may detect a gesture and the position of the hand of the user to provide the detected gesture and position of the hand of the user to the ultrasonic control circuit 120. The user input interface 130 may include a motion sensor 131 and a camera 132. The motion sensor 131 may measure 3D coordinates of a finger and track a hand movement to move the focal point 160. The camera 132 may recognize a finger gesture by use of an RGB or depth camera and adjust an ultrasonic signal based on a specific action. This allows the user to perform an intuitive operation while moving hands in the air and to receive accurate tactile feedback even in a non-contact interface environment.

In various exemplary embodiments of the present disclosure, the signal generation unit 121, the acoustic filtering unit 122, and the resolution adjustment unit 123 of the ultrasonic controller 120 may be implemented by a processor or a plurality of processors in a form of hardware or software, or in a combination of hardware and software

FIG. 2A and FIG. 2B are illustrations for comparing the ultrasonic acoustic pressure control method according to an exemplary embodiment of the present disclosure with a comparative method.

FIG. 2A illustrates a comparative ultrasonic acoustic pressure control method, and FIG. 2B illustrates the ultrasonic acoustic pressure control method according to an exemplary embodiment of the present disclosure.

Referring to FIG. 2A, in the comparative method, a single focal point 160 below a finger 151 is formed. In the comparative method an ultrasonic beam is concentrated at a specific position. Referring to the map at the bottom portion, it may be known that the acoustic pressure is formed only at a fixed spatial resolution. A tactile resolution may remain constant by use of a fixed frequency and a fixed phase array and be adjusted by the user.

In FIG. 2B, the ultrasonic acoustic pressure control method according to an exemplary embodiment of the present disclosure may have an adjustable resolution even when the finger 151 is disposed at the same position. The focal point 160 may adjust a size and a region of the focal point 160 by use of the control window instead of using a single position. Through the acoustic filtering, an acoustic pressure difference between the target region 171 and the suppression region 172 may be maximized. A mathematical algorithm Equation 1 below may be applied to the acoustic filtering method.

$$q = Φ ( {R}_{B} - α {R}_{D} ) \qquad [ Equation l ]$$

$${R}_{D} = \frac{1}{N - 1} \times {Z}_{D} \times {Z}_{D}$$

$${R}_{B} = {Z}_{B} \times {Z}_{B}$$

(where, q denotes a final determined filtered acoustic pressure (acoustic pressure value at a position at which tactile feedback is provided), Φ(A) denotes an eigenvector derived from a largest eigenvalue of matrix A (this is a mathematical model used in a process of filtering so that an ultrasonic signal has directionality), R_{B} denotes an ultrasonic propagation transfer function in the target region 171, Rp denotes an ultrasonic propagation transfer function in the suppression region 172, a denotes a weight coefficient (which adjusts the acoustic pressure difference between the target region 171 and the suppression region 172), Z_{D} denotes a space transfer function between ultrasonic elements and the suppression region (space propagation characteristics of the suppression region), ZB denotes a space transfer function between the ultrasonic elements and the target region (space propagation characteristics of the target region), and N denotes the number of the ultrasonic transducer array.)

Equation 1 represents that the focal point 160 more precise than that of the related art may be formed by filtering to maximize a difference in acoustic pressure between the target region 171 and the suppression region 172, thereby adjusting a driving signal, i.e., controlling strong tactile feedback to occur only at a desired position; suppressing unnecessary acoustic pressure outside the focal point 160; and filtering by use of an eigenvalue.

Referring to the map at the bottom in FIG. 2B, the focal point 160 is not merely a single point. The region of the focal point 160 may be adjusted to adjust the resolution of the focal point 160. When the user moves the hand, the focal point 160 may be adjusted in real-time.

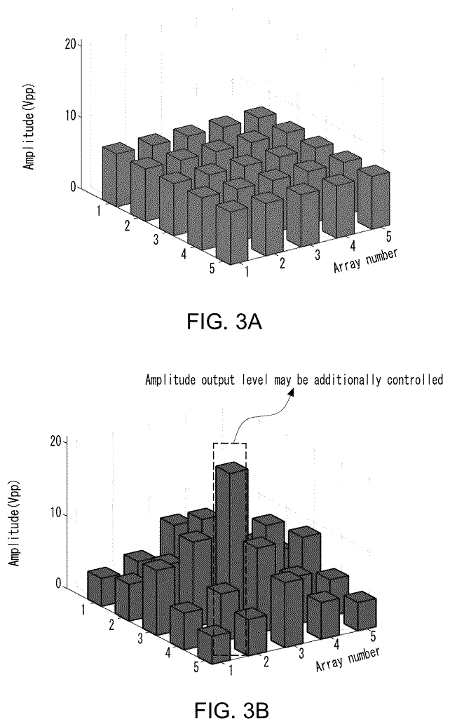

FIG. 3A and FIG. 3B are illustrations for comparing an amplitude variation of each transducer when acoustic filtering is applied in the ultrasonic acoustic pressure control method according to an exemplary embodiment of the present disclosure with a comparative method.

FIG. 3A illustrates an amplitude distribution of the comparative method and FIG. 3B illustrates an amplitude distribution of according to an exemplary embodiment of the present disclosure.

Referring to FIG. 3A, the amplitude distribution of the comparative method shows a uniform amplitude for each transducer (in FIG. 3A, ‘array number’ indicates each transducer). That is, since the focal point 160 is spread wider due to the uniform amplitude of all transducers, it may be difficult to concentrate the acoustic pressure to a specific position when the focal point 160 is formed, and a possibility of occurrence of the grating lobe and the side lobe may increase.

However, referring to FIG. 3B, the amplitude distribution according to an exemplary embodiment of the present disclosure shows that the amplitude is selectively intensified in some transducers, while the amplitudes of specific transducers are relatively low. This represents that not only the simple phase control but also an amplitude level may be adjusted to perform additional control. This may improve acoustic pressure concentration at the target focal point 160 and suppress the grating lobe and the side lobe to minimize unnecessary acoustic pressure outside the focal point.

Since both the phase control and the amplitude control are performed in an exemplary embodiment of the present disclosure, the acoustic pressure concentration in the target region 171 may be improved, and the acoustic pressure in the suppression region 172 may be minimized.

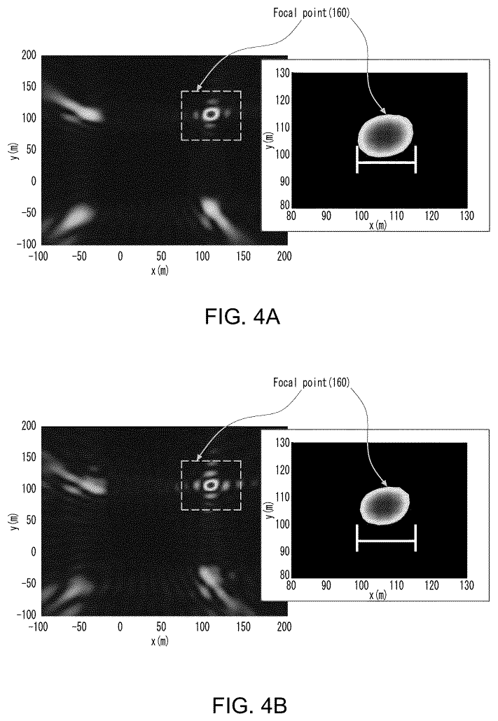

FIG. 4A and FIG. 4B are illustrations for visually comparing an improvement effect of a tactile resolution achieved by the ultrasonic acoustic pressure control method according to an exemplary embodiment of the present disclosure with that achieved by a comparative method.

FIG. 4A illustrates a beam focusing pattern of the comparative method. A beam width is relatively great, and a resolution is low.

FIG. 4B illustrates a beam focusing pattern of the present disclosure. The beam width is relatively reduced compared to that of the comparative method, and the tactile resolution is improved. As the size of the focal point is reduced, more precise tactile feedback may be provided. While the comparative method may not precisely adjust the size of the focal point, the present disclosure may set the control window 170 to use the target region 171 and suppression region 172, thereby precisely adjusting the size of the focal point. As a result, the tactile resolution may be improved to provide more precise tactile feedback.

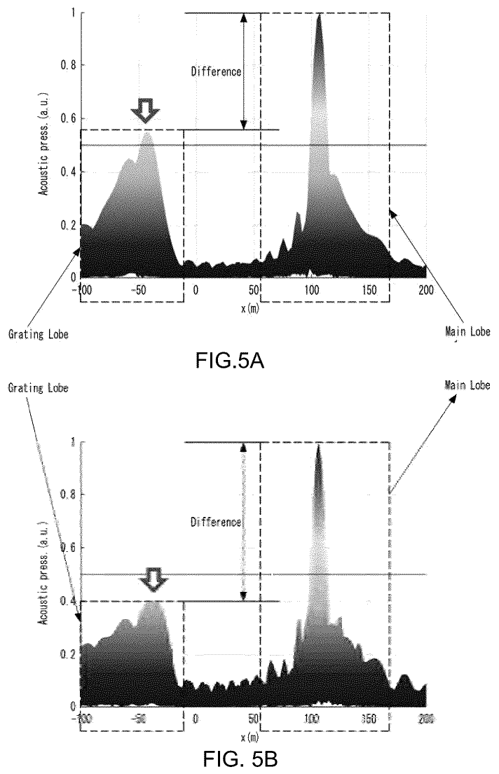

FIG. 5A and FIG. 5B are illustrations for visually comparing an effect of an acoustic filtering according to an exemplary embodiment of the present disclosure with that achieved by a comparative method.

In FIG. 5A, a difference between the main lobe and the grating lobe is relatively small. This may cause unnecessary acoustic interference to degrade a precision of the tactile feedback.

In FIG. 5B, since the grating lobe is reduced by optimally arranging the suppression region 172, the difference between the main lobe and the grating lobe is relatively great. As a result, more precise focal point may be formed, and the acoustic pressure concentration may be improved to provide stronger tactile feedback in the target region 171.

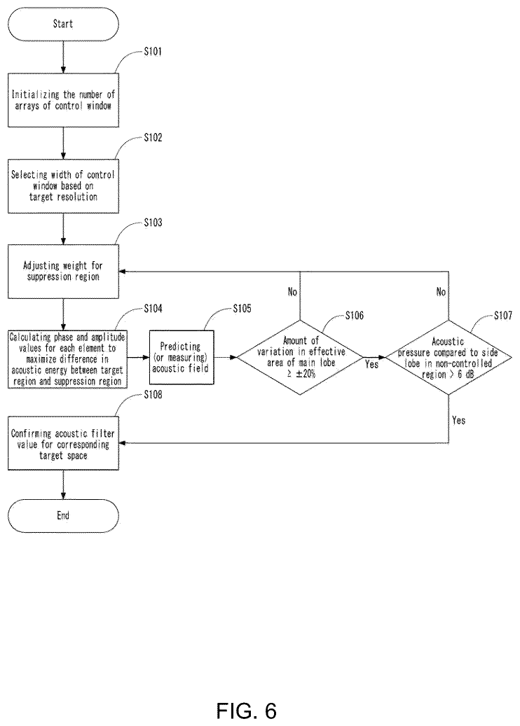

FIG. 6 is a flowchart illustrating a process of generating an acoustic filter value in the ultrasonic acoustic pressure control method according to an exemplary embodiment of the present disclosure.

Referring to FIG. 6, initialization of the number of arrays of a control window 170 is performed in a process S101. Here, the control window 170 that is an element related to a size of a focal point in an ultrasonic transducer array 110 determines a resolution of the focal point. The focal point may be more finely formed by increasing the number of arrays of the control window 170.

After the process S101 of initialization of the number of arrays of the control window 170 is performed, a width of the control window 170 is selected based on a target resolution in a process S102. The width of the control window 170 is selected to adjust the size and the resolution of the focal point. The width of the control window 170 is set to be less than that of the ultrasonic array to increase the resolution of the focal point, and the width of the control window 170 is set to be greater than that of the ultrasonic array to decrease the resolution of the focal point. The user may adjust the resolution of the focal point based on a tactile experience thereof.

After the width of the control window 170 is selected based on the target resolution in the process S102, a weight of the suppression region 172 is adjusted in a process S103. This is a process of minimizing an ultrasonic signal in a specific region to suppress a grating lobe and a side lobe. The process may maximize the acoustic pressure at a specific focal point while reducing the acoustic pressure in an unnecessary region.

After the weight of the suppression region is adjusted in the process S103, phase and amplitude values for each element are determined to maximize a difference in acoustic energy between the target region 171 and the suppression region 172 in a process S104. This is an optimization process for individually adjusting a phase and an amplitude for each transducer 111 to maximize acoustic pressure in the target region 171 and minimize the acoustic pressure in the suppression region 172. That is, the adjusting of the phase and the amplitude may maximize a difference in acoustic energy between the target region 171 and the suppression region 172.

After the phase and amplitude values for each element are determined to maximize the difference in acoustic energy between the target region 171 and the suppression region 172 in the process S104, an acoustic field is predicted or measured in the process S105. This may be a process of performing a simulation or an actual measurement to check whether an ultrasonic wave is correctly formed at a desired focal point.

It is checked in a process S106 whether an amount of variation in effective area of a main lobe is 20% or more. When the above-described condition is not satisfied (No in the process S106), the process S103 of adjusting the weight of the suppression region 172 is performed again. When the above-described condition is satisfied, i.e., when the amount of variation in effective area of the main lobe is 20% or more, it may be understood that the acoustic pressure concentration is not optimized. Thus, the focal point needs to be optimally formed by adjusting the target region 171 and the suppression region 172 again.

When, in the process S106 of checking whether the amount of variation in effective area of the main lobe is 20% or more, the above-described condition is satisfied (Yes in the process S106), and in a process S107 of checking whether the acoustic pressure is greater by 6 dB or more than the side lobe in an non-controlled region, the above-described condition is not satisfied (No in the process S107), the process S103 of adjusting the weight of the suppression region 172 is performed again. Here, the non-controlled refers to an external region that is not affected by the adjustment of the target region 171 and the suppression region 172 and a region in which additional filtering or signal adjustment is not performed. However, when the side lobe (secondary focal point) in the non-controlled region is excessively great, the user may experience unintended tactile feedback. Thus, when the side lobe in the non-controlled region is excessively great, the acoustic filter needs to be additionally adjusted to suppress an unnecessary signal.

When, in the process S106 of checking whether the amount of variation in effective area of the main lobe is 20% or more, the above-described condition is satisfied (Yes in the process S106), and in the process S107 of checking whether the acoustic pressure is greater by 6 dB or more than the side lobe in the non-controlled region, the above-described condition is satisfied (Yes in the process S107), an acoustic filter value for a corresponding target space is confirmed in a process S108. When the above-described two conditions are satisfied, an acoustic filter optimized to the corresponding target space may be generated. Here, the exemplary embodiment of the present disclosure is not limited to the amount of variation in effective area and the reference of the acoustic pressure.

According to at least an exemplary embodiment of the present disclosure, the tactile resolution may be freely adjusted by setting the control window. Accordingly, the high-resolution precise tactile feedback may be provided in the narrow region to enable the fine operation, and the smooth tactile feedback may be provided in the wide region to offer the more natural user experience.

According to at least an exemplary embodiment of the present disclosure, the user may experience the tactile sensation only at the desired specific point by applying the acoustic filtering to effectively suppress the grating lobe and the side lobes. Thus, as the tactile feedback is provided only at the exact position, the risk of malfunction may be reduced, and the reliability in user interface operation may be improved.

According to at least an exemplary embodiment of the present disclosure, the tactile resolution may be improved without increasing the number of ultrasonic transducers. Accordingly, since the high-resolution tactile feedback may be provided by use of the fewer number of ultrasonic transducers in comparison with that of the conventional apparatus, the hardware costs may be reduced, and the size and complexity of the system may be reduced. Thus, the tactile feedback may be realized even in the small-sized apparatus.

According to at least an exemplary embodiment of the present disclosure, when applied to the interfaces for the automotive infotainment system, the augmented reality (AR), and the virtual reality (VR), the user operation convenience may be improved.

Technical objects to be solved by the present disclosure are not limited to the aforementioned technical objects and unmentioned technical objects will be clearly understood by those skilled in the art to which the present disclosure belongs.

It will be apparent to those skilled in the art that various modifications and variations can be made therein without departing from the spirit and scope of the present disclosure. Thus, the detailed description is intended to be illustrative, but not limiting in all aspects. It is intended that the scope of the present disclosure should be determined by the rational interpretation of the claims as set forth, and the modifications and variations of the present disclosure come within the scope of the appended claims and their equivalents.

The method according to the above-described embodiment may be implemented as a program executable on a computer, and the program may be stored on a computer-readable recording medium. Examples of the computer readable recording medium include read-only memory (ROM), random-access memory (RAM), CD-ROMs, magnetic tapes, floppy disks, optical data storage devices, and carrier waves (such as data transmission through the Internet).

The computer readable recording medium may also be distributed over network coupled computer systems so that the computer readable code is stored and executed in a distributed fashion. Furthermore, functional programs, code, and code segments for implementing the above-described method can be readily inferred by programmers skilled in the art to which the exemplary embodiments pertain.

It will be apparent to those skilled in the art that various modifications and variations can be made therein without departing from the spirit and scope of the present disclosure.

Thus, the detailed description is intended to be illustrative, but not limiting in all aspects. It is intended that the scope of the present disclosure should be determined by the rational interpretation of the claims as set forth, and the modifications and variations of the present disclosure come within the scope of the appended claims and their equivalents.

What is claimed is:

1. An ultrasonic acoustic pressure control apparatus comprising:
an ultrasonic transducer array including a plurality of ultrasonic transducers;
an ultrasonic control circuit including a processor, being operatively connected to the ultrasonic transducer array, and controlling the ultrasonic transducer array; and
a user input interface operatively connected to the ultrasonic control circuit, detecting a position and a gesture of a hand of a user, and providing detected information related to the position and the gesture of the hand of the user, to the ultrasonic control circuit,
wherein the ultrasonic control circuit divides a control window set based on the position of the hand into a target region and a suppression region and controls the ultrasonic transducer array so that a difference in acoustic pressure between the target region and the suppression region is adjusted to be greater than or equal to a preset threshold value.

2. The ultrasonic acoustic pressure control apparatus of claim 1, wherein the ultrasonic control circuit controls the ultrasonic transducer array by performing a phase control or an amplitude control for pressure waves generated from the plurality of ultrasonic transducers.

3. The ultrasonic acoustic pressure control apparatus of claim 2, wherein the ultrasonic control circuit:
controls the ultrasonic transducer array to generate a first acoustic pressure in the target region by aligning phases of the pressure waves and increasing amplitudes of the pressure waves in the target region; and
controls the ultrasonic transducer array to generate a second acoustic pressure in the suppression region by dispersing the phases of the pressure waves and reducing the amplitudes of the pressure waves in the suppression region,
wherein a difference between the first acoustic pressure and the second acoustic pressure is greater than or equal to a preset threshold value.

4. The ultrasonic acoustic pressure control apparatus of claim 3, wherein the ultrasonic control circuit reduces a grating lobe and a side lobe in the suppression region.

5. The ultrasonic acoustic pressure control apparatus of claim 1, wherein the ultrasonic control circuit applies an acoustic filtering for the difference in the acoustic pressure between the target region and the suppression region.

6. The ultrasonic acoustic pressure control apparatus of claim 5, wherein the ultrasonic control circuit:
generates, based on a first acoustic pressure transfer function (RB) for the target region and a second acoustic pressure transfer function (RD) for the suppression region, a third acoustic pressure transfer function determined by an equation of RB-αRD, wherein a denotes a weight function that adjusts the difference in the acoustic pressure between the target region and the suppression region; and
uses an eigenvector corresponding to a largest eigenvalue of the third acoustic pressure transfer function.

7. The ultrasonic acoustic pressure control apparatus of claim 1, wherein the ultrasonic control circuit adjusts a size of the control window to adjust a tactile resolution.

8. A method for controlling an ultrasonic acoustic pressure control apparatus, the method comprising:
generating ultrasonic waves by use of an ultrasonic transducer array including a plurality of ultrasonic transducers;
detecting a position and a gesture of a hand of a user to provide detected information related to the position and the gesture of the hand of the user to an ultrasonic control circuit including a processor and operatively connected to the ultrasonic transducer array;
dividing, by the ultrasonic control circuit, a control window set based on the position of the hand into a target region and a suppression region; and
controlling, by the ultrasonic control circuit, the ultrasonic transducer array so that a difference in acoustic pressure between the target region and the suppression region is adjusted to be greater than or equal to a set threshold value.

9. The method of claim 8, wherein the generating of the ultrasonic waves comprises controlling the ultrasonic transducer array by performing a phase control or an amplitude control for pressure waves generated from the plurality of ultrasonic transducers.

10. The method of claim 9, wherein the controlling of the ultrasonic transducer array comprises:
controlling the ultrasonic transducer array to generate a first acoustic pressure in the target region by aligning phases of the pressure waves and increasing amplitudes of the pressure waves in the target region; and
controlling the ultrasonic transducer array to generate a second acoustic pressure in the suppression region by dispersing the phases of the pressure waves and reducing the amplitudes of the pressure waves in the suppression region,
wherein a difference between the first acoustic pressure and the second acoustic pressure is greater than or equal to a preset threshold value.

11. The method of claim 10, wherein the controlling of the ultrasonic transducer array to generate the second acoustic pressure in the suppression region comprises reducing a grating lobe and a side lobe in the suppression region.

12. The method of claim 8, wherein the controlling of the ultrasonic transducer array comprises applying an acoustic filtering for the difference in the acoustic pressure between the target region and the suppression region.

13. The method of claim 12, wherein the applying of the acoustic filtering comprises:
generating, based on a first acoustic pressure transfer function (RB) for the target region and a second acoustic pressure transfer function (RD) for the suppression region, a third acoustic pressure transfer function determined by an equation of RB-αRD, wherein a denotes a weight function that adjusts the difference in the acoustic pressure between the target region and the suppression region; and
using an eigenvector corresponding to a largest eigenvalue of the third acoustic pressure transfer function.

14. The method of claim 8, further comprising adjusting, by the ultrasonic control circuit, a tactile resolution by adjusting a size of the control window and a size of a focal point.

15. A vehicle comprising:
an ultrasonic transducer array including a plurality of ultrasonic transducers;
an ultrasonic control circuit including a processor, being operatively connected to the ultrasonic transducer array, and controlling the ultrasonic transducer array; and
a user input interface operatively connected to the ultrasonic control circuit, detecting a position and a gesture of a hand of a user, and providing detected information related to the position and the gesture of the hand of the user, to the ultrasonic control circuit,
wherein the ultrasonic control circuit divides a control window set based on the position of the hand into a target region and a suppression region and controls the ultrasonic transducer array so that a difference in acoustic pressure between the target region and the suppression region is adjusted to be greater than or equal to a preset threshold value.

16. The vehicle of claim 15, wherein the ultrasonic control circuit controls the ultrasonic transducer array by performing a phase control or an amplitude control for pressure waves generated from the plurality of ultrasonic transducers.

17. The vehicle of claim 16, wherein the ultrasonic control circuit:
controls the ultrasonic transducer array to generate a first acoustic pressure in the target region by aligning phases of the pressure waves and increasing amplitudes of the pressure waves in the target region; and
controls the ultrasonic transducer array to generate a second acoustic pressure in the suppression region by dispersing the phases of the pressure waves and reducing the amplitudes of the pressure waves in the suppression region,
wherein a difference between the first acoustic pressure and the second acoustic pressure is greater than or equal to a preset threshold value.

18. The vehicle of claim 17, wherein the ultrasonic control circuit reduces a grating lobe and a side lobe in the suppression region.

19. The vehicle of claim 15, wherein the ultrasonic control circuit applies an acoustic filtering for the difference in the acoustic pressure between the target region and the suppression region.

20. The vehicle of claim 19, wherein the ultrasonic control circuit:
generates, based on a first acoustic pressure transfer function (RB) for the target region and a second acoustic pressure transfer function (RD) for the suppression region, a third acoustic pressure transfer function determined by an equation of RB-αRD, wherein a denotes a weight function that adjusts the difference in the acoustic pressure between the target region and the suppression region; and
uses an eigenvector corresponding to a largest eigenvalue of the third acoustic pressure transfer function.
